(19) United States
(12) Patent Application Publication
(10) Pub. No.: US 2023/0234163 A1
(43) Pub. Date: Jul. 27, 2023

(54) LASER PROCESSING APPARATUS

(71) Applicant: DISCO CORPORATION, Tokyo (JP)

(72) Inventors: Shogo MATSUDA, Tokyo (JP); Taiki SAWABE, Tokyo (JP)

(21) Appl. No.: 18/150,414

(22) Filed: Jan. 5, 2023

(30) Foreign Application Priority Data
Jan. 27, 2022 (JP) 2022-010841

(51) Int. Cl. B23K 26/03; B23K 26/06; B23K 26/08

(52) U.S. Cl. CPC B23K 26/032; B23K 26/06; B23K 26/0876

(57) ABSTRACT

A laser processing apparatus includes a laser oscillator that emits a laser beam, a beam condenser that condenses the laser beam emitted by the laser oscillator and positions the condensed point to a wafer, a condensed point position adjuster that is disposed between the laser oscillator and the beam condenser and adjusts the position of the condensed point, and an upper surface position detector that detects the upper surface position of the wafer. The upper surface position detector includes a detection light source that emits detection light of a wide wavelength band and a selector that selects detection light with a specific wavelength from the detection light emitted by the detection light source.

### BACKGROUND OF THE INVENTION

### Field of the Invention

The present invention relates to laser processing apparatus.

### Description of the Related Art

A wafer in which plural devices such as an integrated circuit (IC) and large scale integration (LSI) are formed on a front surface in such a manner as to be marked out by plural planned dividing lines that intersect is formed into a desired thickness through grinding of a back surface and thereafter is divided into individual device chips by a laser processing apparatus.

The laser processing apparatus includes a chuck table that holds the wafer, a laser beam irradiation unit that irradiates the wafer held by the chuck table with a laser beam, and a processing feed mechanism that executes processing feed of the chuck table and the laser beam irradiation unit in an X-axis direction and a Y-axis direction orthogonal to the X-axis direction, and can irradiate the planned dividing line of the wafer with the laser beam with high accuracy.

Furthermore, in a technique in which a condensed point of a laser beam with a wavelength having transmissibility with respect to a wafer is positioned to the inside of the wafer corresponding to a planned dividing line and the wafer is irradiated with the laser beam to form a modified layer inside the wafer and thereafter an external force is given to the wafer to divide the wafer into individual device chips, the condensed point of the laser beam needs to be positioned to a proper position from an upper surface of the wafer. Thus, the present applicant has developed techniques for controlling the position of the condensed point of a laser beam while measuring the upper surface position (upper surface height) of a wafer (for example, refer to Japanese Patent Laid-open No. 2005-313182 and Japanese Patent Laid-open No. 2007-152355).

The technique disclosed in Japanese Patent Laid-open No. 2005-313182 is a technique of a first type that irradiates the upper surface of a wafer with detection light emitted by a detection light source with an angle α of incidence and includes an image sensor that measures the position of reflected light arising from reflection at the upper surface of the wafer and calculates the upper surface position of the wafer depending on the position of the reflected light detected by the image sensor.

The technique disclosed in Japanese Patent Laid-open No. 2007-152355 is a technique of a second type that irradiates the upper surface of a wafer held by a chuck table with detection light emitted by a detection light source through a beam condenser and splits reflected light arising from reflection at the upper surface of the wafer into a first optical path and a second optical path and compares the intensity of the reflected light that has passed through a slit mask disposed on the first optical path and the intensity of the reflected light guided to the second optical path to calculate the upper surface position of the wafer.

### SUMMARY OF THE INVENTION

However, depending on the kind and surface state of the wafer, the detection light emitted from the detection light source does not sufficiently reflect at the upper surface of the wafer in some cases. There is a problem that it is impossible to properly measure the upper surface height of the wafer in such a case. This problem is frequently found in the measuring instrument of the first type and possibly occurs also in the measuring instrument of the second type.

Thus, an object of the present invention is to provide laser processing apparatus that can properly measure the upper surface height of a wafer irrespective of the kind and surface state of the wafer.

In accordance with an aspect of the present invention, there is provided laser processing apparatus including a chuck table that holds a wafer, a laser beam irradiation unit that irradiates the wafer held by the chuck table with a laser beam, and a feed mechanism that executes processing feed of the chuck table and the laser beam irradiation unit in an X-axis direction and a Y-axis direction orthogonal to the X-axis direction. The laser beam irradiation unit includes a laser oscillator that emits the laser beam, a beam condenser that condenses the laser beam emitted by the laser oscillator and positions a condensed point to the wafer held by the chuck table, a condensed point position adjuster that is disposed between the laser oscillator and the beam condenser and adjusts the position of the condensed point, and an upper surface position detector that detects the upper surface position of the wafer. The upper surface position detector includes a detection light source that emits detection light of a wide wavelength band and a selector that selects detection light with a specific wavelength from the detection light emitted by the detection light source. The upper surface position detector selects, by the selector, the detection light with the specific wavelength in the detection light emitted by the detection light source, and guides the detection light to an upper surface of the wafer held by the chuck table and calculates the upper surface position of the wafer by reflected light arising from reflection at the upper surface of the wafer.

Preferably, the selector includes a plurality of band-pass filters that allow transmission of detection light with specific wavelengths different from each other, and selects any of the plurality of band-pass filters and positions the selected band-pass filter to an optical path of the detection light to select the detection light with the specific wavelength. Preferably, the selector selects the detection light with a wavelength that maximizes the amount of received light.

Preferably, the upper surface position detector includes a combiner that causes the detection light that is the detection light emitted by the detection light source and has passed through the selector and a first beam splitter sequentially to merge into between the laser oscillator and the condensed point position adjuster and a second beam splitter that splits reflected light arising from reflection of the detection light that has passed through the condensed point position adjuster and the beam condenser at the upper surface of the wafer held by the chuck table into a first optical path and a second optical path through the combiner and the first beam splitter. The upper surface position detector includes also a filter that is disposed in the first optical path and causes a part of the split reflected light to pass through the filter, a first light receiving element that receives the reflected light that has passed through the filter, and a second light receiving element that is disposed in the second optical path and receives the whole of the split reflected light. The upper surface position detector calculates the upper surface position of the wafer from comparison between the amount of received light at the first light receiving element and the amount of received light at the second light receiving element.

Preferably, the upper surface position detector includes an irradiating end part that irradiates the upper surface of the wafer with the detection light emitted by the detection light source with an angle α of incidence, a light receiving end part that receives reflected light arising from reflection of the detection light with which the irradiation is executed from the irradiating end part at the upper surface of the wafer, and an image sensor that measures the position of the reflected light received by the light receiving end part. The upper surface position detector calculates the upper surface position of the wafer on the basis of the position of the reflected light detected by the image sensor.

According to the laser processing apparatus of the present invention, the detection light with the specific wavelength that sufficiently reflects at the upper surface of the wafer can be selected and the upper surface height of the wafer can be properly measured irrespective of the kind and surface state of the wafer.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a laser processing apparatus of an embodiment of the present invention;

FIG. 2 is a block diagram of a laser beam irradiation unit illustrated in FIG. 1;

FIG. 3 is a perspective view of first and second galvano scanners illustrated in FIG. 2;

FIG. 4 is a schematic diagram illustrating an optical path length of a laser beam that passes through the first galvano scanner illustrated in FIG. 3;

FIG. 5 is a graph illustrating a relation between the installation angle of the first and second galvano scanners illustrated in FIG. 3 and change in the optical path length of the laser beam;

FIG. 6 is a graph illustrating a relation between the optical path length of the laser beam and change in a distance from a beam condenser to the condensed point;

FIG. 7 is a perspective view of a selector illustrated in FIG. 2;

FIG. 8A is a schematic diagram illustrating an area of reflection when a wafer is irradiated with detection light;

FIG. 8B is a schematic diagram illustrating the area of reflection when the condensed point of the detection light is positioned on the lower side compared with the case illustrated in FIG. 8A;

FIG. 9 is a graph illustrating the relation between a ratio of voltage signals output from first and second light receiving elements illustrated in FIG. 2 and a distance from the upper surface of the wafer to the condensed point of the detection light;

FIG. 10 is a perspective view of the beam condenser and a second upper surface position detector illustrated in FIG. 1;

FIG. 11 is a schematic diagram illustrating the state in which the upper surface position of the wafer is being detected by the second upper surface position detector illustrated in FIG. 1; and

FIG. 12 is a schematic diagram illustrating the optical path of the detection light when the upper surface position of the wafer is a reference position and the optical path of the detection light when the upper surface position of the wafer has changed from the reference position by h.

### DETAILED DESCRIPTION OF THE PREFERRED EMBODIMENT

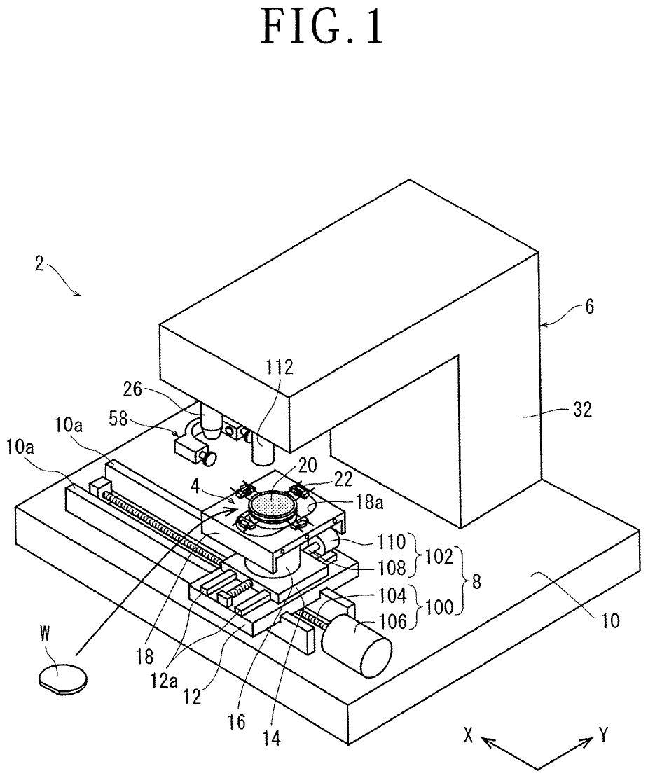

A Laser processing apparatus of an embodiment of the present invention will be described in detail below with reference to the drawings. As illustrated in FIG. 1, a laser processing apparatus 2 includes a chuck table 4 that holds a wafer W, a laser beam irradiation unit 6 that irradiates the wafer W held by the chuck table 4 with a laser beam, and a feed mechanism 8 that executes processing feed of the chuck table 4 and the laser beam irradiation unit 6 in an X-axis direction indicated by an arrow X in FIG. 1 and a Y-axis direction (direction indicated by an arrow Y in FIG. 1) orthogonal to the X-axis direction. The XY plane defined by the X-axis direction and the Y-axis direction is substantially horizontal.

The laser processing apparatus 2 of the present embodiment includes an X-axis movable plate 12 mounted over the upper surface of a base 10 movably in the X-axis direction, a Y-axis movable plate 14 mounted over the upper surface of the X-axis movable plate 12 movably in the Y-axis direction, a support column 16 fixed to the upper surface of the Y-axis movable plate 14, and a cover plate 18 fixed to the upper end of the support column 16. An elongated hole 18 a extending in the Y-axis direction is formed in the cover plate 18. Furthermore, the above-described chuck table 4 is rotatably mounted on the upper end of the support column 16 and passes through the elongated hole 18 a of the cover plate 18 to extend upward.

A porous circular suction adhesion chuck 20 connected to suction means (not illustrated) is disposed at an upper end part of the chuck table 4. Plural clamps 22 are disposed at the circumferential edge of the chuck table 4 at intervals in the circumferential direction.

In the chuck table 4, a suction force is generated for the upper surface of the suction adhesion chuck 20 by the suction means to suck and hold the wafer W placed on the upper surface of the suction adhesion chuck 20. Moreover, the chuck table 4 is rotated with the upward-downward direction being the axial center by a motor (not illustrated) for the chuck table incorporated in the support column 16.

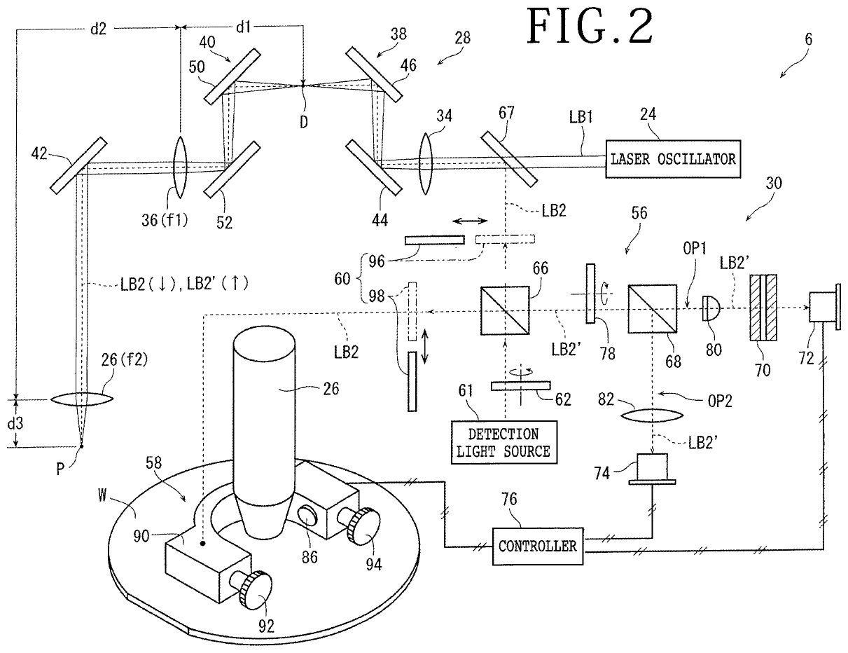

As illustrated in FIG. 2, the laser beam irradiation unit 6 includes a laser oscillator 24 that emits a pulse laser beam LB1 for processing, a beam condenser 26 that condenses the laser beam LB1 emitted by the laser oscillator 24 and positions a condensed point P to the wafer W held by the chuck table 4, a condensed point position adjuster 28 that is disposed between the laser oscillator 24 and the beam condenser 26 and adjusts the position of the condensed point P, and an upper surface position detector 30 that detects the upper surface position of the wafer W.

As illustrated in FIG. 1, the laser beam irradiation unit 6 includes a housing 32 that extends upward from the upper surface of the base 10 and subsequently extends substantially horizontally. The laser oscillator 24 is disposed inside the housing 32. The laser beam LB1 emitted by the laser oscillator 24 has, for example, a wavelength having transmissibility with respect to the wafer W (for example, 1064 nm). The beam condenser 26 is mounted on the lower surface of the tip of the housing 32.

Referring to FIG. 2, the condensed point position adjuster 28 includes first and second lenses 34 and 36 disposed at an interval from each other, a first galvano scanner 38 that reflects the laser beam LB1 that has passed through the first lens 34, and a second galvano scanner 40 that reflects the laser beam LB1 reflected at the first galvano scanner 38 and guides the laser beam LB1 to the second lens 36. Between the second lens 36 and the beam condenser 26, a direction change mirror 42 that guides the laser beam LB1 that has passed through the second lens 36 to the beam condenser 26 is disposed.

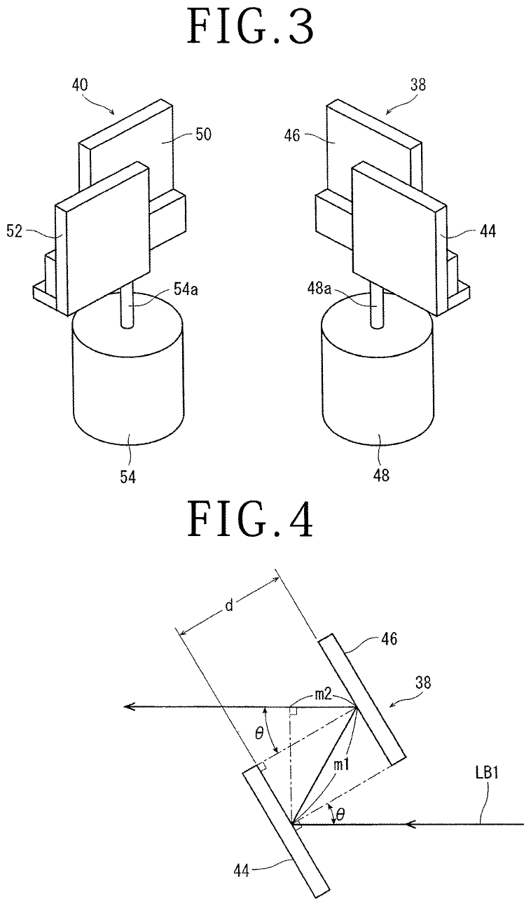

Referring to FIG. 3 with FIG. 2, the first galvano scanner 38 has a pair of first and second mirrors 44 and 46 installed to face each other in parallel at a predetermined interval and an angle adjusting actuator 48 (see FIG. 3) that adjusts the installation angle of the first and second mirrors 44 and 46.

As illustrated in FIG. 2, the first mirror 44 reflects the laser beam LB1 that has passed through the first lens 34 toward the second mirror 46. The second mirror 46 reflects the laser beam LB1 reflected at the first mirror 44 toward the second galvano scanner 40.

As illustrated in FIG. 3, a rotating shaft 48 a of the angle adjusting actuator 48 is coupled to both the first and second mirrors 44 and 46. Furthermore, the angle adjusting actuator 48 changes the installation angle of the first and second mirrors 44 and 46 with respect to the optical path of the laser beam LB1 while keeping the parallel state of the first and second mirrors 44 and 46.

Similarly to the first galvano scanner 38, the second galvano scanner 40 has a pair of third and fourth mirrors 50 and 52 installed to face each other in parallel at a predetermined interval and an angle adjusting actuator 54 that adjusts the installation angle of the third and fourth mirrors 50 and 52.

The third mirror 50 reflects the laser beam LB1 reflected at the second mirror 46 of the first galvano scanner 38 toward the fourth mirror 52. The fourth mirror 52 reflects the laser beam LB1 reflected at the third mirror 50 toward the second lens 36.

A rotating shaft 54a of the angle adjusting actuator 54 is coupled to both the third and fourth mirrors 50 and 52. Furthermore, the angle adjusting actuator 54 changes the installation angle of the third and fourth mirrors 50 and 52 with respect to the optical path of the laser beam LB1 while keeping the parallel state of the third and fourth mirrors 50 and 52.

As described above, the laser beam LB1 emitted by the laser oscillator 24 reflects at the first and second mirrors 44 and 46 after passing through the first lens 34. As illustrated in FIG. 4, when the interval between the first mirror 44 and the second mirror 46 is defined as d, m1 and m2 are represented by the following expressions.

m1=d/cos θ

m2=m1 cos 2θ=(d/cos θ)cos 2θ

Thus, the following relation is obtained.

m1+m2=(d/cos θ)(1+cos 2θ)=2d cos θ

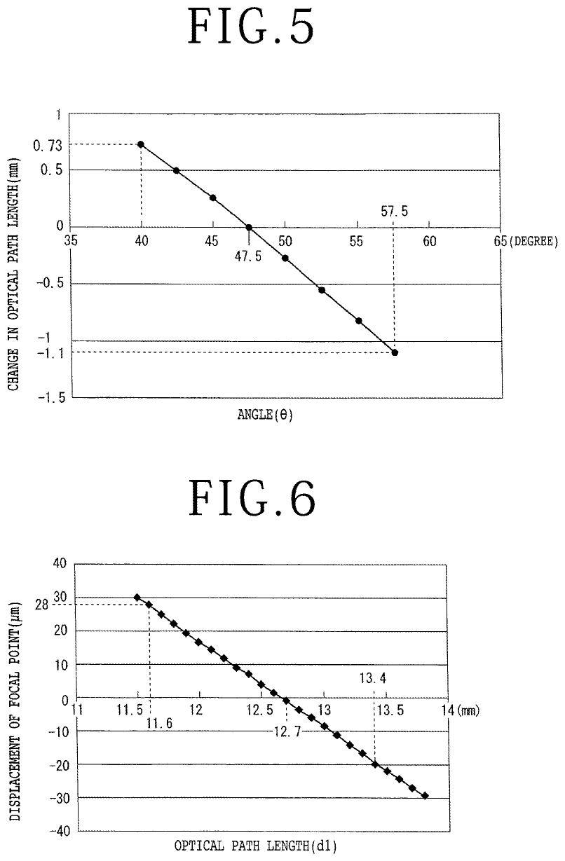

When the interval between the third mirror 50 and the fourth mirror 52 is also defined as d similarly to the above, the optical path length of the laser beam LB1 changes in (m1+m2)×2. For example, when the interval d is set to 2 mm and the state in which the angle θ is 47.5 degrees is employed as the basis (change in the optical path length is 0), change in the optical path length of the laser beam LB1 becomes as illustrated in FIG. 5. In the example illustrated in FIG. 5, when the angle θ changes in a range from 40 degrees to 57.5 degrees, the optical path length changes in a range from +0.73 to −1.1 mm. That is, the amount of change in the optical path length in the above-described angel range is 1.83 mm.

Next, description will be made about the relation between the change in the optical path length and the displacement of the position of the condensed point of the laser beam LB1 condensed by the beam condenser 26.

As illustrated in FIG. 2, when the optical path length from a focusing point D of the first lens 34 to the second lens 36 is defined as d1 and the optical path length from the second lens 36 to the beam condenser 26 is defined as d2 and the focal length of the second lens 36 is defined as f1 and the focal length of the beam condenser 26 is defined as f2, a distance d3 from the beam condenser 26 to the condensed point P can be obtained by the following expression (1).

$$d 3 = \frac{d 1 + d 2 ( - \frac{d 1}{f 1} + 1 )}{\frac{1}{f 2} \{ d 1 + d 2 ( - \frac{d 1}{f 1} + 1 ) \} - ( - \frac{d 1}{f 1} + 1 )} \qquad ( 1 )$$

The focusing point D of the first lens 34 corresponds with the focal length of the first lens 34 when the laser beam LB1 emitted by the laser oscillator 24 is a collimated beam.

When, in expression (1), a specific numerical value is substituted for each of the focal length f1 of the second lens 36, the focal length f2 of the beam condenser 26, and the optical path length d2 from the second lens 36 to the beam condenser 26, the distance d3 from the beam condenser 26 to the condensed point P becomes a function of the optical path length d1 from the focusing point D of the first lens 34 to the second lens 36. That is, the position of the condensed point P changes when the optical path length d1 is changed.

For example, when the focal length f1 of the second lens 36 is set to 12.7 mm and the focal length f2 of the beam condenser 26 is set to 2 mm and the optical path length d2 is set to 20 mm and the state in which the optical path length d1 corresponds with the focal length f1 (12.7 mm) of the second lens 36 is employed as the basis (displacement of the condensed point P is 0), the displacement of the condensed point P with respect to change in the optical path length d1 becomes as illustrated in FIG. 6.

Therefore, under the above-described condition, when the angle θ changes in the range from 40 degrees to 57.5 degrees, the optical path length changes in the range from +0.73 to −1.1 mm. In addition, corresponding to this, the distance d3 from the beam condenser 26 to the condensed point P changes in a range from −20 to +28 μm. That is, in the condensed point position adjuster 28, the position of the condensed point P in the upward-downward direction is adjusted by adjusting the installation angle of the first to fourth mirrors 44, 46, 50, and 52 by the angle adjusting actuators 48 and 54.

As illustrated in FIG. 2, the upper surface position detector 30 of the present embodiment includes a first upper surface position detector 56, a second upper surface position detector 58, and a choosing part 60 that chooses either the first upper surface position detector 56 or the second upper surface position detector 58. The upper surface position detector 30 does not need to include both the first and second upper surface position detectors 56 and 58 and it suffices for the upper surface position detector 30 to include either the first or second upper surface position detector 56 or 58.

The first upper surface position detector 56 includes a light source 61 for detection that emits detection light LB2 of a wide wavelength band and a selector 62 that selects the detection light LB2 with a specific wavelength from the detection light LB2 emitted by the light source 61 for detection. The first upper surface position detector 56 selects, by the selector 62, the detection light LB2 with the specific wavelength in the detection light LB2 emitted by the light source 61 for detection, and guides the detection light LB2 to the upper surface of the wafer W held by the chuck table 4 and calculates the upper surface position of the wafer W by reflected light LB2′ arising from reflection at the upper surface of the wafer W.

The light source 61 for detection emits, for example, light with wavelengths in a range of 100 to 2000 nm as the detection light LB2 of the wide wavelength band. The wide wavelength band of the detection light LB2 is not limited to the above-described range (range of 100 to 2000 nm) and it suffices for the wide wavelength band to be a range that allows selective extraction of plural beams of detection light with wavelengths different from each other.

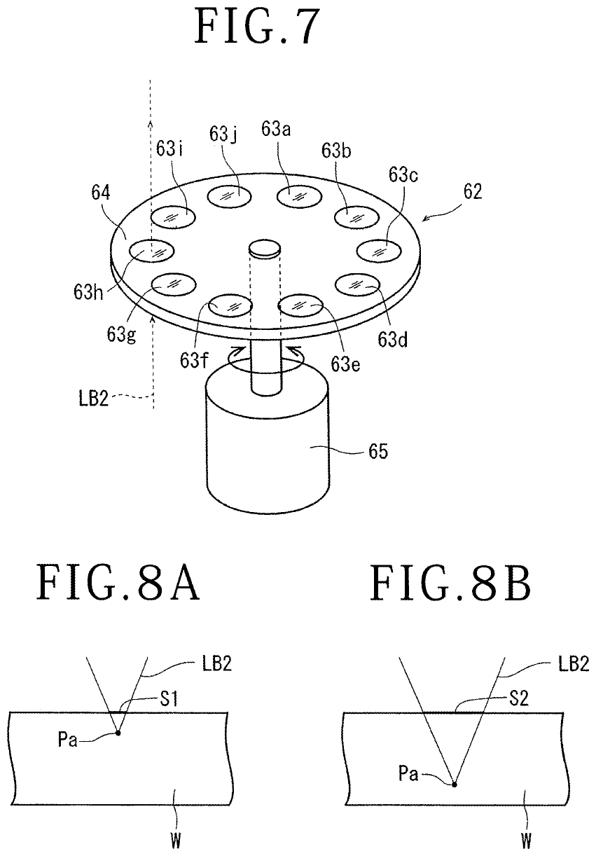

As illustrated in FIG. 7, the selector 62 has plural band-pass filters 63a to 63j, a support plate 64 that supports the plural band-pass filters 63a to 63j, and a motor 65 that rotates the support plate 64.

The plural band-pass filters 63a to 63j each allow transmission of the detection light LB2 with a respective one of specific wavelengths different from each other. For example, the respective band-pass filters 63a to 63j can be configured to allow transmission of light with the following wavelength: 100 nm with the band-pass filter 63a; 300 nm with the band-pass filter 63b; 500 nm with the band-pass filter 63c; 700 nm with the band-pass filter 63d; 900 nm with the band-pass filter 63e; 1100 nm with the band-pass filter 63f; 1300 nm with the band-pass filter 63g; 1500 nm with the band-pass filter 63h; 1700 nm with the band-pass filter 63i; and 1900 nm with the band-pass filter 63j.

The number of band-pass filters of the selector 62 and the wavelengths of light transmitted through the band-pass filters of the selector 62 can be optionally set.

Furthermore, in the selector 62, the support plate 64 is rotated by the motor 65 and any of the plural band-pass filters 63a to 63j is selected and is positioned to the optical path of the detection light LB2. This can select the detection light LB2 with the specific wavelength that sufficiently reflects at the upper surface of the wafer W in the detection light LB2 of the wide wavelength band emitted by the light source 61 for detection. The selector 62 selects the detection light LB2 with a wavelength different from the wavelength of the laser beam LB1 for processing emitted by the laser oscillator 24.

It is preferable for the selector 62 to select the detection light with a wavelength that maximizes the amount of received light at first and second light receiving elements 72 and 74 or a light receiving end part 86 to be described later according to the kind of wafer W and the surface state of the wafer W. This is because the upper surface height of the wafer W can be measured more accurately.

As illustrated in FIG. 2, the first upper surface position detector 56 includes a combiner 67 that causes the detection light LB2 that is the detection light LB2 emitted by the light source 61 for detection and has passed through the selector 62 and a first beam splitter 66 sequentially to merge into between the laser oscillator 24 and the condensed point position adjuster 28 and a second beam splitter 68 that splits the reflected light LB2′ arising from reflection of the detection light LB2 that has passed through the condensed point position adjuster 28 and the beam condenser 26 at the upper surface of the wafer W held by the chuck table 4 into a first optical path OP1 and a second optical path OP2 through the combiner 67 and the first beam splitter 66. The first upper surface position detector 56 further includes a filter 70 that is disposed on the first optical path OP1 and causes part of the split reflected light LB2′ to pass through the filter 70, the first light receiving element 72 that receives the reflected light LB2′ that has passed through the filter 70, and the second light receiving element 74 that is disposed on the second optical path OP2 and receives the whole of the split reflected light LB2′.

The combiner 67 can be configured from a dichroic half-mirror. The combiner 67 causes the laser beam LB1 emitted by the laser oscillator 24 to pass through the combiner 67 and reflects the detection light LB2 that is the detection light LB2 emitted by the light source 61 for detection and has passed through the first beam splitter 66 toward the condensed point position adjuster 28. The first and second light receiving elements 72 and 74 output a voltage signal corresponding to the amount of received light to a controller 76.

The controller 76 is configured from a computer and controls actuation of the laser processing apparatus 2. The controller 76 includes a central processing unit (CPU) that executes calculation processing according to a control program, a read only memory (ROM) that stores the control program and so forth, and a readable-writable random access memory (RAM) that stores a calculation result and so forth.

The first upper surface position detector 56 of the present embodiment further includes a filter 78 that allows transmission of only light corresponding to the wavelength of the reflected light LB2′ (specific wavelength selected by the selector 62) in the light that has been guided from the combiner 67 to the first beam splitter 66 and reflected at the first beam splitter 66, a cylindrical lens 80 that one-dimensionally condenses the reflected light LB2′ split into the first optical path OP1 by the second beam splitter 68, and a condensing lens 82 that condenses, at 100%, the reflected light LB2′ split into the second optical path OP2 by the second beam splitter 68.

The configuration of the filter 78 may be the same as the configuration of the above-described selector 62 and has plural band-pass filters, a support plate that supports the plural band-pass filters, and a motor that rotates the support plate although not illustrated.

Furthermore, in the filter 78, the band-pass filter that allows transmission of light with the same wavelength as the wavelength selected in the selector 62 in the plural band-pass filters is selected and is positioned to the optical path of the reflected light LB2′. This allows only the light corresponding to the wavelength of the reflected light LB2′ (specific wavelength selected by the selector 62) to be transmitted through the filter 78.

The detection light LB2 of the wide wavelength band emitted by the light source 61 for detection passes through the first beam splitter 66 after selection of only the specific wavelength by the selector 62 and then is reflected at the combiner 67 toward the condensed point position adjuster 28 and is guided to the beam condenser 26 through the condensed point position adjuster 28 and the direction change mirror 42. Then, the detection light LB2 with the specific wavelength condensed by the beam condenser 26 reflects at the upper surface of the wafer W held by the chuck table 4.

For example, as illustrated in FIG. 8A, when a condensed point Pa of the detection light LB2 is at a position comparatively close to the upper surface of the wafer W, the detection light LB2 reflects at an area S1 of irradiation of the upper surface of the wafer W.

The reflected light LB2′ reflected at the upper surface of the wafer W goes through the beam condenser 26, the direction change mirror 42, the condensed point position adjuster 28, the combiner 67, and the first beam splitter 66 and reaches the filter 78 as illustrated by a dashed line in FIG. 2.

Reflected light of the laser beam LB1 for processing also reaches the filter 78 similarly to the reflected light LB2′ of the detection light LB2. However, the reflected light of the laser beam LB1 for processing is interrupted by the filter 78. This is because the filter 78 causes only the light corresponding to the wavelength of the reflected light LB2′ of the detection light LB2 to be passed through the filter 78 as described above. Therefore, only the reflected light LB2′ of the detection light LB2 passes through the filter 78.

The reflected light LB2′ that has passed through the filter 78 is split into the first optical path OP1 and the second optical path OP2 by the second beam splitter 68. The reflected light LB2′ split into the first optical path OP1 is one-dimensionally focused by the cylindrical lens 80 and the section thereof becomes an elliptical shape. The reflected light LB2′ focused into the elliptical shape as the section is restricted into a predetermined unit length by the filter 70 and part of the reflected light LB2′ split into the first optical path OP1 is received by the first light receiving element 72. Then, a voltage signal corresponding to the amount of received light is output from the first light receiving element 72.

Furthermore, as illustrated in FIG. 8B, when the condensed point Pa of the detection light LB2 is deeper than the position illustrated in FIG. 8A, the detection light LB2 reflects at an area S2 of irradiation of the upper surface of the wafer W. The area S2 is larger than the area S1 (S2>S1). Thus, the length of the major axis when the section of the reflected light relating to the area S2 is narrowed into the elliptical shape by the cylindrical lens 80 on the first optical path OP1 becomes longer than the length of the major axis when the section of the reflected light relating to the area S1 is narrowed into the elliptical shape.

As described above, the reflected light LB2′ whose section has been narrowed into the elliptical shape on the first optical path OP1 is restricted into the predetermined unit length by the filter 70 and is received by the first light receiving element 72. Thus, the amount of received light when the reflected light relating to the area S2 is received by the first light receiving element 72 becomes smaller than the amount of received light when the reflected light relating to the area S1 is received by the first light receiving element 72.

As above, the amount of received light of the reflected light received by the first light receiving element 72 becomes larger when the condensed point Pa of the detection light LB2 is closer to the upper surface of the wafer W, and becomes smaller when the condensed point Pa is remoter from the upper surface of the wafer W. Therefore, when the upper surface position (reflection position) of the wafer W changes, the amount of received light of the first light receiving element 72 changes and the voltage signal output from the first light receiving element 72 changes.

On the other hand, the reflected light LB2′ split into the second optical path OP2 is condensed at 100% by the condensing lens 82 and therefore the whole of the reflected light LB2′ split into the second optical path OP2 is received by the second light receiving element 74. Thus, even when the upper surface position (reflection position) of the wafer W changes, the amount of received light of the second light receiving element 74 does not change. Therefore, the amount of received light of the second light receiving element 74 is larger than that of the first light receiving element 72. In addition, the voltage signal output from the second light receiving element 74 is constant.

The relation between the ratio of the voltage signals output from the first and second light receiving elements 72 and 74 (V2/V1) and a distance from the upper surface of the wafer W to the condensed point Pa of the detection light LB2 is as in a graph illustrated in FIG. 9, for example.

The abscissa axis of FIG. 9 indicates the distance (pm) from the upper surface of the wafer W to the condensed point Pa in the case in which the condensed point Pa is positioned to the inside of the wafer W. Furthermore, the ordinate axis of FIG. 9 indicates the ratio of a voltage signal V1 output from the first light receiving element 72 and a voltage signal V2 output from the second light receiving element 74 (V2/V1).

In the example illustrated in FIG. 9, the ratio (V2/V1) of the voltage signals becomes “3” when the condensed point Pa is located at a depth of 10 μm from the upper surface of the wafer W, and the ratio (V2/V1) of the voltage signals becomes “6” when the condensed point Pa is located at a depth of 40 μm from the upper surface of the wafer W.

Furthermore, in the first upper surface position detector 56, from the comparison between the amount of received light at the first light receiving element 72 that changes depending on the upper surface position of the wafer W and the amount of received light at the second light receiving element 74 that does not change depending on the upper surface position of the wafer W, the upper surface position of the wafer W is calculated by the controller 76 on the basis of the position of the condensed point Pa of the detection light LB2.

Similarly to the first upper surface position detector 56, the second upper surface position detector 58 includes the light source 61 for detection that emits the detection light LB2 of a wide wavelength band and the selector 62 that selects the detection light LB2 with a specific wavelength from the detection light LB2 emitted by the light source 61 for detection. Moreover, the second upper surface position detector 58 selects, by the selector 62, the detection light LB2 with the specific wavelength in the detection light LB2 emitted by the light source 61 for detection, and guides the detection light LB2 to the upper surface of the wafer W held by the chuck table 4 and calculates the upper surface position of the wafer W by reflected light LB2″ arising from reflection at the upper surface of the wafer W.

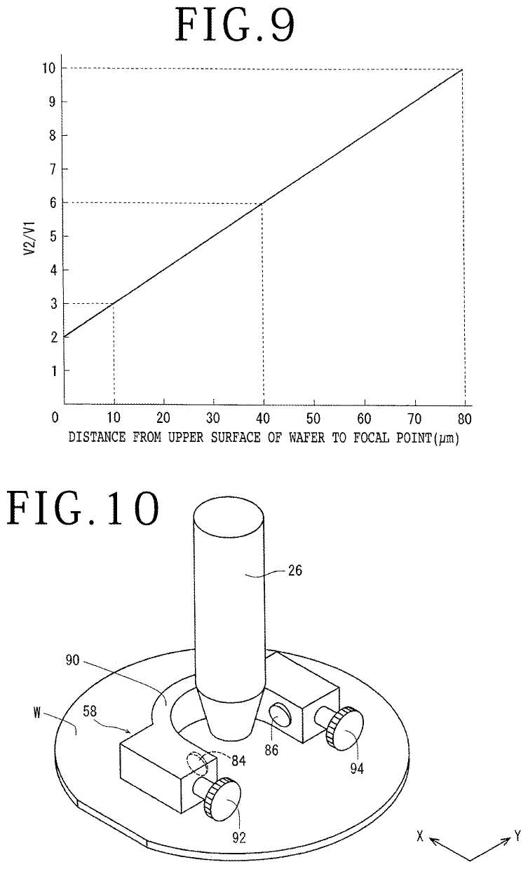

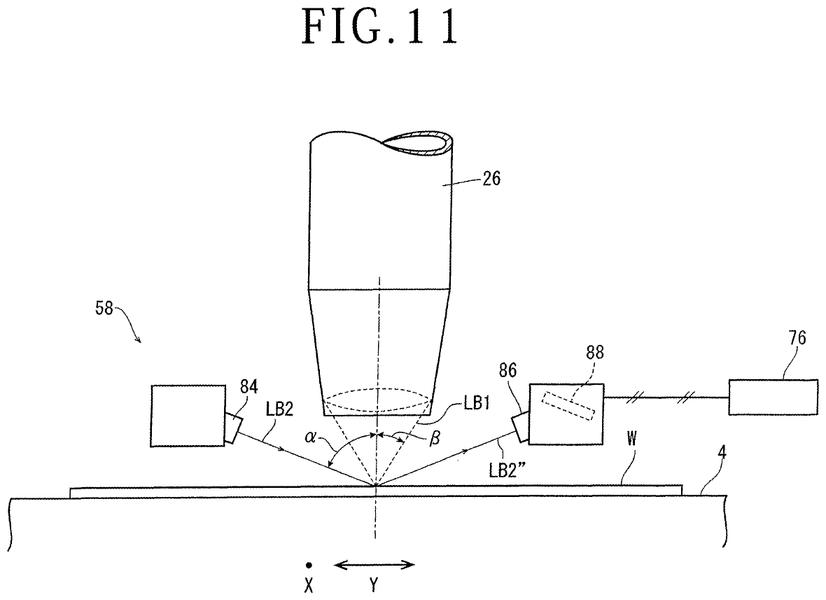

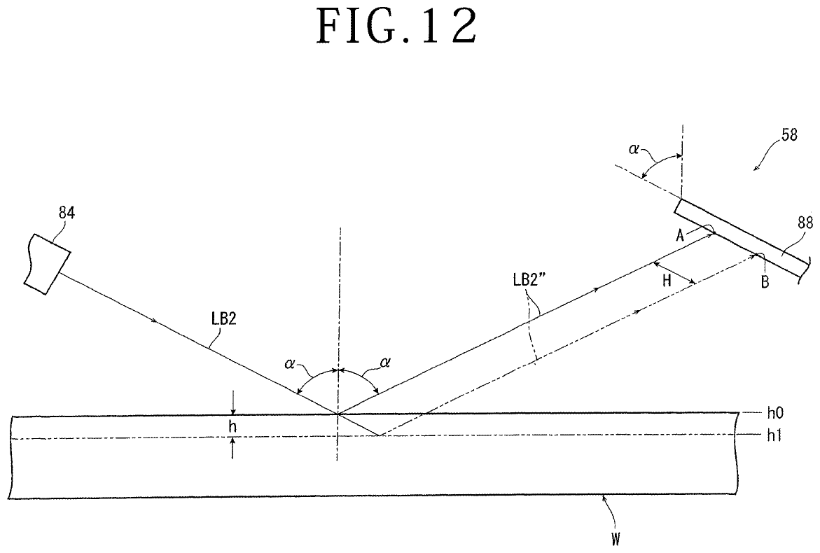

Referring to FIG. 10 and FIG. 11, the second upper surface position detector 58 includes an irradiating end part 84 (see FIG. 11) that irradiates the upper surface of the wafer W with the detection light LB2 emitted by the light source 61 for detection with an angle α of incidence, the light receiving end part 86 that receives the reflected light LB2″ arising reflection of the detection light LB2 with which the irradiation is executed from the irradiating end part 84 at the upper surface of the wafer W, and an image sensor 88 (see FIG. 11) that measures the position of the reflected light LB2″ received by the light receiving end part 86.

The second upper surface position detector 58 of the present embodiment includes a U-shaped casing 90 as illustrated in FIG. 10. The casing 90 is supported by the housing 32 of the laser beam irradiation unit 6 with the interposition of an appropriate bracket (not illustrated). Furthermore, the irradiating end part 84 and the light receiving end part 86 are disposed on this casing 90. As illustrated in FIG. 11, the irradiating end part 84 and the light receiving end part 86 are disposed at an interval in the Y-axis direction with the interposition of the beam condenser 26.

As illustrated in FIG. 2, the detection light LB2 of the wide wavelength band emitted by the light source 61 for detection is guided to the casing 90 of the second upper surface position detector 58 through the first beam splitter 66 after only the specific wavelength is selected by the selector 62. Then, as illustrated in FIG. 11, the upper surface of the wafer W held by the chuck table 4 is irradiated with the detection light LB2 with the specific wavelength guided to the casing 90 from the irradiating end part 84 with the angle α of incidence.

As illustrated in FIG. 11, the angle α of incidence is the angle formed by a straight line perpendicular to the upper surface of the chuck table 4 and the detection light LB2 with which the irradiation is executed from the irradiating end part 84. The angle α of incidence is set to an angle that is larger than a condensing angle β of the beam condenser 26 and is smaller than 90 degrees (β<α<90). The position of the irradiation with the detection light LB2 by the irradiating end part 84 substantially corresponds with the irradiation position of the laser beam LB1 for processing with which the wafer W is irradiated from the beam condenser 26.

The light receiving end part 86 is disposed at a position to which the detection light LB2 output from the irradiating end part 84 travels through regular reflection at the upper surface of the wafer W. As illustrated in FIG. 12, the image sensor 88 is disposed in such a manner that the angle formed by the straight line perpendicular to the upper surface of the chuck table 4 and the image sensor 88 is α.

Moreover, as illustrated in FIG. 10, angle adjustment knobs 92 and 94 for adjusting the inclination angle of the irradiating end part 84 and the light receiving end part 86 are annexed to the casing 90. The angle α of incidence of the detection light LB2 with which the irradiation is executed from the irradiating end part 84 and the angle of light reception of the light receiving end part 86 can be adjusted by rotating the angle adjustment knobs 92 and 94.

When the upper surface position of the wafer W is a position indicated by a solid line in FIG. 12, the detection light LB2 output from the irradiating end part 84 reflects at the upper surface of the wafer W and is received at point A on the image sensor 88. Furthermore, when the upper surface position of the wafer W is a position indicated by a two-dot chain line in FIG. 12, the detection light LB2 output from the irradiating end part 84 reflects at the upper surface of the wafer W as illustrated by a two-dot chain line and is received at point B on the image sensor 88. Data detected by the image sensor 88 is output to the controller 76.

Then, the upper surface position of the wafer W is calculated by the controller 76 on the basis of the position of the reflected light LB2″ detected by the image sensor 88. Specifically, displacement h of the upper surface position of the wafer W is calculated based on an interval H between point A and point B detected by the image sensor 88 (h=H cos α).

For example, in the case in which the upper surface position of the wafer W when the reflected light LB2″ is detected at point A on the image sensor 88 is defined as a reference position h0, an upper surface position h1 of the wafer W when the reflected light LB2″ is detected at point B on the image sensor 88 can be obtained by h1=h0−h because the displacement h of the upper surface position of the wafer W when the reflected light LB2″ is detected at point B can be calculated by h=H cos α as described above. As above, in the second upper surface position detector 58, the upper surface position of the wafer W is calculated based on the position of the reflected light LB2″ detected by the image sensor 88.

Referring to FIG. 2, the choosing part 60 includes first and second shutters 96 and 98, a first actuator (not illustrated) that moves the first shutter 96, and a second actuator (not illustrated) that moves the second shutter 98.

The first shutter 96 is positioned, by the first actuator, to a permission position (position indicated by a solid line in FIG. 2) at which the first shutter 96 permits passing of the detection light LB2 that has passed through the first beam splitter 66 and an interruption position (position indicated by a two-dot chain line in FIG. 2) at which the first shutter 96 interrupts the detection light LB2 that has passed through the first beam splitter 66.

The second shutter 98 is positioned, by the second actuator, to a permission position (position indicated by a solid line in FIG. 2) at which the second shutter 98 permits passing of the detection light LB2 reflected at the first beam splitter 66 and an interruption position (position indicated by a two-dot chain line in FIG. 2) at which the second shutter 98 interrupts the detection light LB2 reflected at the first beam splitter 66.

Moreover, in the choosing part 60, the detection light LB2 split by the first beam splitter 66 is chosen by the first shutter 96 and the second shutter 98.

Specifically, when the choosing part 60 chooses the first upper surface position detector 56, the first shutter 96 is positioned to the permission position by the first actuator and the second shutter 98 is positioned to the interruption position by the second actuator.

In this case, the detection light LB2 that has been emitted from the light source 61 for detection and passed through the first beam splitter 66 is guided to the first upper surface position detector 56. Meanwhile, the detection light LB2 that has been emitted from the light source 61 for detection and reflected at the first beam splitter 66 is interrupted by the second shutter 98. Therefore, the first upper surface position detector 56 is chosen.

Furthermore, when the choosing part 60 chooses the second upper surface position detector 58, the first shutter 96 is positioned to the interruption position by the first actuator and the second shutter 98 is positioned to the permission position by the second actuator.

In this case, the detection light LB2 that has been emitted from the light source 61 for detection and passed through the first beam splitter 66 is interrupted by the first shutter 96. Meanwhile, the detection light LB2 that has been emitted from the light source 61 for detection and reflected at the first beam splitter 66 is guided to the second upper surface position detector 58. Therefore, the second upper surface position detector 58 is chosen.

As illustrated in FIG. 1, the feed mechanism 8 includes an X-axis feed mechanism 100 that executes processing feed of the chuck table 4 in the X-axis direction relative to the laser beam irradiation unit 6 and a Y-axis feed mechanism 102 that executes processing feed of the chuck table 4 in the Y-axis direction relative to the laser beam irradiation unit 6.

The X-axis feed mechanism 100 has a ball screw 104 that is coupled to the X-axis movable plate 12 and extends in the X-axis direction and a motor 106 that rotates the ball screw 104. The X-axis feed mechanism 100 converts rotational motion of the motor 106 to linear motion by the ball screw 104 and transmits the linear motion to the X-axis movable plate 12 to move the X-axis movable plate 12 in the X-axis direction along guide rails 10a on the base 10. Thereby, processing feed of the chuck table 4 is executed in the X-axis direction.

The Y-axis feed mechanism 102 has a ball screw 108 that is coupled to the Y-axis movable plate 14 and extends in the Y-axis direction and a motor 110 that rotates the ball screw 108. The Y-axis feed mechanism 102 converts rotational motion of the motor 110 to linear motion by the ball screw 108 and transmits the linear motion to the Y-axis movable plate 14 to move the Y-axis movable plate 14 in the Y-axis direction along guide rails 12a on the X-axis movable plate 12. Thereby, processing feed of the chuck table 4 is executed in the Y-axis direction.

As illustrated in FIG. 1, the laser processing apparatus 2 further includes an imaging unit 112 that detects a processing target part for which laser processing should be executed by the laser beam irradiation unit 6. The imaging unit 112 is mounted on the lower surface of the tip of the housing 32 of the laser beam irradiation unit 6. An image obtained by imaging by the imaging unit 112 is output to the controller 76.

Next, a method in which the wafer W is processed by using the above-described laser processing apparatus 2 will be described. In the present embodiment, first, the wafer W is placed on the upper surface of the chuck table 4. Subsequently, the suction means connected to the suction adhesion chuck 20 is actuated and the wafer W is sucked and held by the upper surface of the suction adhesion chuck 20. Next, the X-axis feed mechanism 100 is actuated and the chuck table 4 is positioned directly under the imaging unit 112.

After the chuck table 4 is positioned directly under the imaging unit 112, the wafer W is imaged by the imaging unit 112. Subsequently, the positional relation between the wafer W and the beam condenser 26 is adjusted based on an image of the wafer W imaged by the imaging unit 112. At this time, the laser beam LB1 for processing is aimed at the processing target part for which laser processing should be executed. In addition, the condensed point P of the laser beam LB1 for processing is adjusted to a predetermined position (for example, a position at a predetermined depth from the upper surface of the wafer W).

Subsequently, the support plate 64 is rotated by the motor 65 of the selector 62 and any of the plural band-pass filters 63a to 63j is selected and is positioned to the optical path of the detection light LB2. This can select the detection light LB2 with the specific wavelength that sufficiently reflects at the upper surface of the wafer W in the detection light LB2 of the wide wavelength band emitted by the light source 61 for detection.

At this time, it is preferable to select the detection light with a wavelength that maximizes the amount of received light at the first and second light receiving elements 72 and 74 or the light receiving end part 86 in view of more accurate measurement of the upper surface height of the wafer W. Thus, it is preferable to, in advance, irradiate the upper surface of the wafer W with the detection light LB2 with plural specific wavelengths that can be selected by the selector 62 and check the wavelength that maximizes the amount of received light.

Next, either the first or second upper surface position detector 56 or 58 is chosen by the choosing part 60. Subsequently, irradiation with the laser beam LB1 for processing from the beam condenser 26 is executed while the chuck table 4 is moved by the feed mechanism 8 to cause the condensed point P of the laser beam LB1 for processing to sequentially pass through the processing target part of the wafer W.

Furthermore, the wafer W is irradiated with the detection light LB2 with the specific wavelength selected by the selector 62 and detection of the upper surface position of the wafer W is executed. Then, the height of the condensed point P of the laser beam LB1 for processing is adjusted based on the detection result of the upper surface position of the wafer W.

In the case in which the first upper surface position detector 56 is chosen, when the wafer W is irradiated with the detection light LB2 with the specific wavelength, the voltage signal relating to the amount of received light of the first light receiving element 72 and the voltage signal relating to the amount of received light of the second light receiving element 74 are sent to the controller 76.

In this case, the upper surface position of the wafer W is calculated by the controller 76 from comparison between the amount of received light at the first light receiving element 72 and the amount of received light at the second light receiving element 74. Then, based on the calculated upper surface position of the wafer W, the angle adjusting actuators 48 and 54 of the first and second galvano scanners 38 and 40 of the condensed point position adjuster 28 are controlled by the controller 76 and the height of the condensed point P of the laser beam LB1 for processing is adjusted.

On the other hand, in the case in which the second upper surface position detector 58 is chosen, when the wafer W is irradiated with the detection light LB2 with the specific wavelength, position information of the reflected light LB2″ detected by the image sensor 88 of the second upper surface position detector 58 is sent to the controller 76.

In this case, the upper surface position of the wafer W is calculated by the controller 76 on the basis of the position information of the reflected light LB2″ detected by the image sensor 88. Then, based on the calculated upper surface position of the wafer W, the angle adjusting actuators 48 and 54 of the first and second galvano scanners 38 and 40 of the condensed point position adjuster 28 are controlled by the controller 76 and the height of the condensed point P of the laser beam LB1 for processing is adjusted.

Due to this, the distance from the upper surface of the wafer W to the condensed point P of the laser beam LB1 for processing is kept constant. Therefore, requisite laser processing (for example, formation of a modified layer) can be executed at a position at a predetermined depth from the upper surface of the wafer W in parallel to the upper surface of the wafer W.

As described above, in the laser processing apparatus 2 of the present embodiment, the detection light LB2 with the specific wavelength that sufficiently reflects at the upper surface of the wafer W in the detection light LB2 of the wide wavelength band emitted by the light source 61 for detection is selected by the selector 62. Therefore, the upper surface height of the wafer W can be properly measured irrespective of the kind and surface state of the wafer W and it becomes possible to properly position the condensed point P of the laser beam LB1 for processing on the basis of the upper surface height of the wafer W properly measured.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A laser processing apparatus comprising:
a chuck table that holds a wafer;
a laser beam irradiation unit that irradiates the wafer held by the chuck table with a laser beam; and
a feed mechanism that executes processing feed of the chuck table and the laser beam irradiation unit in an X-axis direction and a Y-axis direction orthogonal to the X-axis direction,
wherein the laser beam irradiation unit includes
a laser oscillator that emits the laser beam,
a beam condenser that condenses the laser beam emitted by the laser oscillator and positions a condensed point to the wafer held by the chuck table,
a condensed point position adjuster that is disposed between the laser oscillator and the beam condenser and adjusts a position of the condensed point, and
an upper surface position detector that detects an upper surface position of the wafer,
wherein the upper surface position detector includes
a detection light source that emits detection light of a wide wavelength band, and
a selector that selects detection light with a specific wavelength from the detection light emitted by the detection light source, and
the upper surface position detector selects, by the selector, the detection light with the specific wavelength in the detection light emitted by the detection light source, and guides the detection light to an upper surface of the wafer held by the chuck table and calculates the upper surface position of the wafer by reflected light arising from reflection at the upper surface of the wafer.

2. The laser processing apparatus according to claim 1,
wherein the selector includes a plurality of band-pass filters that allow transmission of detection light with specific wavelengths different from each other, and selects any of the plurality of band-pass filters and positions the selected band-pass filter to an optical path of the detection light to select the detection light with the specific wavelength.

3. The laser processing apparatus according to claim 1,
wherein the selector selects the detection light with a wavelength that maximizes an amount of received light.

4. The laser processing apparatus according to claim 1,
wherein the upper surface position detector includes
a combiner that causes the detection light that is the detection light emitted by the detection light source and has passed through the selector and a first beam splitter sequentially to merge into between the laser oscillator and the condensed point position adjuster,
a second beam splitter that splits reflected light arising from reflection of the detection light that has passed through the condensed point position adjuster and the beam condenser at the upper surface of the wafer held by the chuck table into a first optical path and a second optical path through the combiner and the first beam splitter,
a filter that is disposed in the first optical path and causes a part of the split reflected light to pass through the filter,
a first light receiving element that receives the reflected light that has passed through the filter, and
a second light receiving element that is disposed in the second optical path and receives whole of the split reflected light, and
the upper surface position detector calculates the upper surface position of the wafer from comparison between an amount of received light at the first light receiving element and an amount of received light at the second light receiving element.

5. The laser processing apparatus according to claim 1,
wherein the upper surface position detector includes
an irradiating end part that irradiates the upper surface of the wafer with the detection light emitted by the detection light source with an angle α of incidence,
a light receiving end part that receives reflected light arising from reflection of the detection light with which the irradiation is executed from the irradiating end part at the upper surface of the wafer, and
an image sensor that measures a position of the reflected light received by the light receiving end part, and
the upper surface position detector calculates the upper surface position of the wafer on a basis of the position of the reflected light detected by the image sensor.
